(19) United States
(12) Patent Application Publication
(10) Pub. No.: US 2026/0254426 A1
(43) Pub. Date: Aug. 27, 2026

(54) Differential Amplifier Circuit with Distributed Chopper Circuitry Having a Cyclic Rest Phase

(71) Applicant: Apple Inc., Cupertino, CA (US)

(72) Inventors: Erhan Ozalevli, Cupertino, CA (US); Evaldo M Miranda, JR., Saratoga, CA (US)

(21) Appl. No.: 19/063,263

(22) Filed: Feb. 25, 2025

(51) Int. Cl. H03F 3/387

(52) U.S. Cl. CPC H03F 3/387

(57) ABSTRACT

The current disclosure is directed to a differential amplifier with a cyclically rotating rest phase. Different portions of the differential amplifier may be coupled to different portions of distributed chopper circuitry. The chopper circuitry may deactivate, remove, or rest at least one portion of the differential amplifier during each time step of an amplifier operation to generate an output signal. The chopper circuitry may shift the deactivated portion of the differential amplifier. In particular, the chopper circuitry may activate at least one deactivated portion and deactivate at least one activated portion of the differential amplifier at each subsequent time step during the amplifier operation. Moreover, the chopper circuitry may shift the deactivated portion back to a first deactivated portion of the differential amplifier after shifting the rest phase through the entirety of the portion of the differential amplifier. As such, the differential amplifier may generate the output signal with reduced noise.

### BACKGROUND

The present disclosure relates generally to differential amplifier circuits and electronic devices including the differential amplifier circuits.

Electronic devices consume power provided by a power supply. To this end, electronic devices often include an amplifier circuit to provide amplified voltage and/or current signals to one or more components of the electronic device. The amplifier circuit may generate an output signal based on an input signal. The amplifier circuit may provide the output signal with a desired voltage values and/or current value. For example, the desired voltage values and/or current value may be associated with a supply power rating of the one or more other components of the electronic device receiving the output signals. However, in many cases, the amplifier circuit may generate the output signal with undesired noise that may distort the voltage and/or current value of the output signals.

### SUMMARY

This disclosure is generally directed to an amplifier circuit for generating amplified signals during operations. The amplifier circuit may include a differential amplifier and distributed chopper circuitry having a cyclic rest phase during the operations of the amplifier circuit. The distributed chopper circuitry may reduce a random telegraph noise (RTN) and/or a flicker (1/f) noise of the amplifier circuit by implementing the cyclic rest phase during the operations of the amplifier circuit. As such, the amplifier circuit may generate the amplified signals with an improved signal-to-noise ratio (SNR).

The differential amplifier may include multiple transistors controlled by the distributed chopper circuitry to generate the amplified signals. The distributed chopper circuitry may include multiple input chopper circuits, multiple output chopper circuits, and multiple input pairs of amplifier input transistors. As the amplifier input transistors are paired, the input chopper circuits and the output chopper circuits associated with each input pair of amplifier input transistors may be paired. As such, the distributed chopper circuitry may include multiple pairs of input chopper circuits and output chopper circuits. For example, each input chopper circuit and output chopper circuit pair may be coupled to two or more of the transistors of the differential amplifier.

A controller may activate the amplifier circuit by resting at least one of the input chopper circuit and output chopper circuit pairs, hereinafter referred to as pairs, to amplify input signals during an operation. In some cases, the amplifier differential input transistor may also be referred to as pairs. The operation may span over multiple time steps. During each time step, each of the pairs may have either of an active phase or a rest phase. Moreover, at each time step, at least one pair may have the rest phase while the remainder of the pairs may have the active phase. During the operation, the controller may shift the rest phase through the pairs based on a resting frequency. For example, the resting frequency may correspond to one or more time steps based on a chopping frequency or a multiple of the chopping frequency.

In particular, the controller may activate a portion of the pairs to have the active phase at each time step. Moreover, at each time step, the controller may deactivate or rest at least one pair (or a remainder of the pairs) to have the rest phase. As such, at least one pair may be in the rest phase at each time step. At a subsequent time step, the controller may shift the rest phase to at least one subsequent pair. For example, at the subsequent time step, the controller may activate at least one of the deactivated pairs and deactivate at least one of the activated pairs.

The controller may cyclically rotate the rest phase through the pairs by shifting the rest phase. For example, the controller may cyclically shift the rest phase back to a first deactivated pair after shifting the rest phase through the entirety of the pairs during the operation. Accordingly, each of the pairs may be rested (e.g., deactivated) at least once when the controller shifts the rest phase through the entirety of the pairs during the operation of the amplifier.

With the foregoing in mind, each pair may deactivate two or more transistors of the differential amplifier coupled thereto during a respective rest phase. The transistors coupled to the rested pair may be rested during the rest phase of the pair. In some cases, the transistors may release at least a portion of undesired trapped electrical charges while being rested. For example, a rested transistor may release at least a portion of the undesired electrical charges trapped in a semiconductor material of the transistor that had been accumulated during previous active phases of the pair coupled to the transistor. As such, the rested transistor may exhibit reduced RTN and/or flicker noise to generate at least a portion of the amplified signals with an improved SNR during subsequent active phases of the pair coupled to the transistor. Moreover, as mentioned above, the rest phase may cyclically rotate through the pairs during the operation. Accordingly, the amplifier circuit may generate the amplified signals with an improved SNR.

### BRIEF DESCRIPTION OF THE DRAWINGS

Various aspects of this disclosure may be better understood upon reading the following detailed description and upon reference to the drawings described below in which like numerals refer to like parts.

FIG. 1 is a block diagram of an electronic device including a differential amplifier circuit with distributed chopper circuitry having a cyclic rest phase, according to embodiments of the present disclosure;

FIG. 2 is a front view of a handheld device representing an example of the electronic device of FIG. 1, according to embodiments of the present disclosure;

FIG. 3 is a front view of another handheld device representing another example of the electronic device of FIG. 1, according to embodiments of the present disclosure;

FIG. 4 is a perspective view of a notebook computer representing an example of the electronic device of FIG. 1, according to embodiments of the present disclosure;

FIG. 5 illustrates front and side views of a wearable electronic device representing another example of the electronic device of FIG. 1, according to embodiments of the present disclosure;

FIG. 6 is a block diagram of a portion of the electronic device of FIGS. 1-5 including an amplifier circuit with a differential amplifier and distributed chopper circuitry having a shifting rest phase, according to embodiments of the present disclosure;

FIG. 7 is a circuit diagram of the amplifier circuit of FIG. 6 with the differential amplifier and the distributed chopper circuitry having a shifting rest phase, according to embodiments of the present disclosure;

FIG. 8 is a block diagram of a portion of the electronic device of FIGS. 1-5 including the amplifier circuit of FIG. 6 having the distributed chopper circuitry and the differential amplifier including multiple segments, according to embodiments of the present disclosure;

FIG. 9 is a circuit diagram of a portion of the electronic device of FIGS. 1-5 depicting a segment of the amplifier circuit of FIG. 8, according to embodiments of the present disclosure;

FIG. 10 is a process flow diagram illustrating an embodiment of a process of providing an output signal by the amplifier circuit of FIGS. 6-9 to one or more components of the electronic device, in accordance with an aspect of the present disclosure;

FIG. 11 is a timing diagram of a first example of operations of distributed chopper circuitry illustrating synchronized shifting of rest phases and active phases of four pairs of the input chopper circuits and the output chopper circuits, according to embodiments of the present disclosure;

FIG. 12 is a timing diagram illustrating a second example of operations of distributed chopper circuitry for cyclically rotating a rest phase of four transistor pairs of the amplifier circuit every sixteen time steps while chopping each two transistor pairs of the amplifier circuit over four time steps, according to embodiments of the present disclosure; and

FIG. 13 is a timing diagram illustrating a third example of operations of distributed chopper circuitry for cyclically rotating a rest phase of four transistor pairs of the amplifier circuit every eighteen time steps while chopping each two transistor pairs of the amplifier circuit over three time steps, according to embodiments of the present disclosure.

### DETAILED DESCRIPTION OF SPECIFIC EMBODIMENTS

When introducing elements of various embodiments of the present disclosure, the articles “a,” “an,” and “the” are intended to mean that there are one or more of the elements. The terms “including” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. Furthermore, the particular features, structures, or characteristics may be combined in any suitable manner in one or more embodiments. Use of the terms “approximately,” “near,” “about,” “close to,” and/or “substantially” should be understood to mean including close to a target (e.g., design, value, amount), such as within a margin of any suitable or contemplatable error (e.g., within 0.1 % of a target, within 1% of a target, within 5% of a target, within 10% of a target, within 25% of a target, and so on). Moreover, it should be understood that any exact values, numbers, measurements, and so on, provided herein, are contemplated to include approximations (e.g., within a margin of suitable or contemplatable error) of the exact values, numbers, measurements, and so on. Additionally, the term “set” may include one or more. That is, a set may include a unitary set of one member or a set may include multiple members. Furthermore, the term “continuous” may correspond to an activity that occurs without interruption or a consecutive repetition with a relatively short time period therebetween. Furthermore, the phrase A “based on” B is intended to mean that A is at least partially based on B. Moreover, the term “or” is intended to be inclusive (e.g., logical OR) and not exclusive (e.g., logical XOR). In other words, the phrase A “or” B is intended to mean A, B, or both A and B.

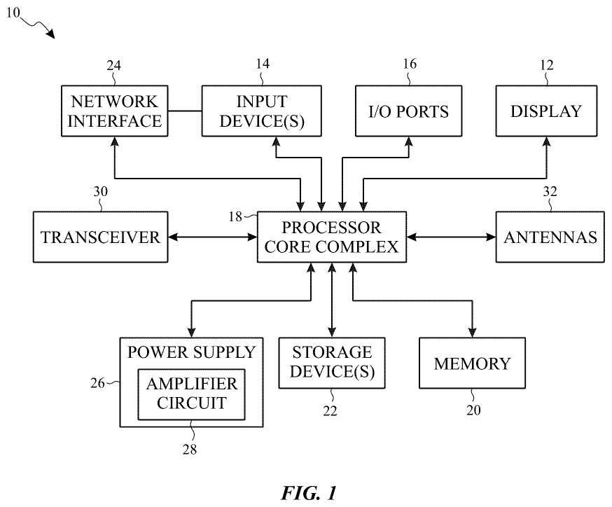

FIG. 1 is a block diagram of an electronic device 10, according to embodiments of the present disclosure. As is described in more detail below, the electronic device 10 may be any suitable electronic device, such as a computer, a mobile phone, a portable media device, a tablet, a television, a virtual reality headset, a wearable device such as a watch, a vehicle dashboard, or the like. Thus, it should be noted that FIG. 1 is merely one example of a particular implementation and is intended to illustrate the types of components that may be present in an electronic device 10.

The electronic device 10 may include an electronic display 12, one or more input devices 14, one or more input/output (I/O) ports 16, a processor core complex 18 having one or more processing circuitry(s) or processing circuitry cores, local memory 20, a main memory storage device 22, a network interface 24, a power supply 26 (e.g., power source), transceiver 30, and one or more antennas 32. The various components described in FIG. 1 may include hardware elements (e.g., circuitry), software elements (e.g., a tangible, non-transitory computer readable medium storing executable instructions), or a combination of both hardware and software elements. It should be noted that the various depicted components may be combined into fewer components or separated into additional components. For example, the local memory 20 and the main memory storage device 22 may be included in a single component.

The processor core complex 18 is operably coupled with local memory 20 and the main memory storage device 22. Thus, the processor core complex 18 may execute instructions stored in local memory 20 and/or the main memory storage device 22 to perform operations, such as generating or transmitting control signals to one or more components of the electronic device 10. As such, the processor core complex 18 may include one or more processors, one or more general purpose microprocessors, one or more application specific integrated circuits (ASICs), one or more programmable logic devices (PLDs) such as field programmable gate arrays (FPGAs), or any combination thereof. In some embodiments, a system on a chip (SoC) may include the processor core complex 18, among other things.

In addition to program instructions, the local memory 20 or the main memory storage device 22 may store data to be processed by the processor core complex 18. Thus, the local memory 20 and/or the main memory storage device 22 may include one or more tangible, non-transitory, computer readable media. For example, the local memory 20 may include random access memory (RAM) and the main memory storage device 22 may include read-only memory (ROM), rewritable non-volatile memory such as flash memory, hard drives, optical discs, or the like.

The network interface 24 may communicate data with another electronic device or a network. For example, the network interface 24 (e.g., a radio frequency system) may enable the electronic device 10 to communicatively couple to a personal area network (PAN), such as a Bluetooth network, a local area network (LAN), such as an 802.11x Wi-Fi network, or a wide area network (WAN), such as a 4G, Long-Term Evolution (LTE), or 5G cellular network.

The power supply 26 may provide electrical power to the various components of the electronic device 10. For example, the power supply 26 may provide the electrical power to the electronic display 12, the input devices 14, the I/O ports 16, the processor core complex 18, the local memory 20, the main memory storage device 22, the network interface 24, the power supply 26, the transceiver 30, or a combination thereof, among other things. The power supply 26 may include any suitable source of energy, such as a rechargeable lithium polymer (Li-poly) battery or an alternating current (AC) power converter.

The power supply 26 may include one or more amplifier circuits 28 for providing the electrical power. It should be appreciated that in alternative or additional embodiments, any combination of the electronic display 12, the input devices 14, the I/O ports 16, the processor core complex 18, the local memory 20, the main memory storage device 22, the network interface 24, the power supply 26, the transceiver 30, and the antennas 32, among other things, may include one or more amplifier circuits 28. An amplifier circuit 28 may provide a differential output signal (e.g., an amplified signal, V_{OUT}) to one or more components in the electronic device 10. For example, the amplifier circuit 28 may provide the differential output signal to a power supply rail and/or a ground terminal coupled to the one or more components in the electronic device 10. The amplifier circuit 28 may include a differential amplifier and distributed chopper circuitry. The differential amplifier may include multiple transistor pairs to generate the output signal.

The amplifier circuit 28 may generate the output signal differentially during an operation spanning multiple time steps. At each time step, the distributed chopper circuitry may activate a portion of the amplifier circuit 28 to amplify differential input signals while resting a remaining portion of the amplifier circuit 28. For example, at each time step, the distributed chopper circuitry may activate a portion of the amplifier circuit 28 by activating a number of the transistor pairs. Moreover, at each time step, the distributed chopper circuitry may rest a remaining portion of the amplifier circuit 28 by resting a remainder (e.g., at least one) of the transistor pairs. The distributed chopper circuitry may deactivate each transistor of each of the deactivated transistor pairs.

To activate each transistor pair, the distributed chopper circuitry may chop or switch (e.g., change) polarities of transistors of the transistor pair during consecutive time steps. The distributed chopper circuitry may chop or switch polarities of transistors of a transistor pair by switching positive and negative signals of the differential input signal being received by each transistor of the transistor pair. As such, the distributed chopper circuitry may switch positive and negative signals of the differential output signal being generated by each transistor of the transistor pair.

For example, the distributed chopper circuitry may chop or switch polarities of a first transistor of a transistor pair coupled to a positive input terminal and a positive output terminal of the amplifier circuit 28 by recoupling the transistor to a negative input terminal and a negative output terminal of the amplifier circuit 28. Moreover, the distributed chopper circuitry may chop or switch polarities of a second transistor of the transistor pair coupled to the negative input terminal and the negative output terminal of the amplifier circuit 28 by recoupling the transistor to the positive input terminal and the positive output terminal of the amplifier circuit 28.

The transceiver 30 may include transmitters and receivers coupled via communication buses to transmit and receive data. In some embodiments, the transceiver 30 may include circuitry for data communication using any version of a serializer and deserializer (SerDes) interface, a peripheral component interconnect express (PCIe) interface, or any other viable interfacing protocol, such as various communication standards. It should be appreciated that the transceiver 30 may include and/or utilize any viable circuitry to facilitate data communication between multiple circuits, components, chips, integrated circuits (ICs), and so on. For example, the transceiver 30 may be coupled to a first chip and a second chip to provide a chip-to-chip (C2C) interface. Moreover, it should be appreciated that the primary circuit and the secondary circuit of the transceiver 30 may communicate via a wired link (e.g., a bus) or a wireless link. For example, the transceiver 30 may use any viable communication protocol, such as Wi-Fi, 4G LTE, or 5G NR, among other possibilities, to establish and communicate using the wireless link.

The I/O ports 16 may enable the electronic device 10 to interface with other electronic devices. For example, when a portable storage device is connected, the I/O port 16 may enable the processor core complex 18 to communicate data with the portable storage device. The input devices 14 may enable user interaction with the electronic device 10, for example, by receiving user inputs via a button, a keyboard, a mouse, a trackpad, or the like. The input device 14 may include touch-sensing components in the electronic display 12. The touch sensing components may receive user inputs by detecting occurrence or position of an object touching the surface of the electronic display 12.

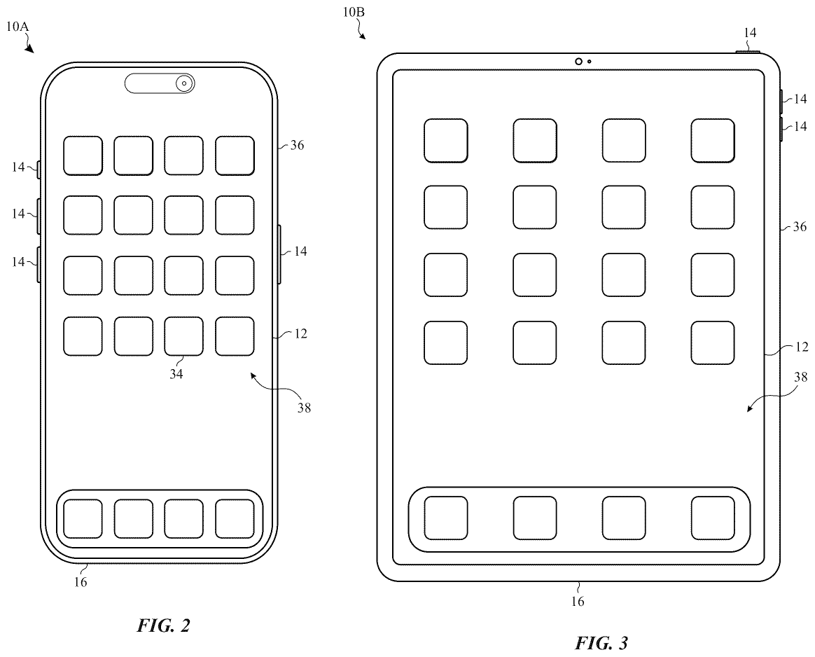

The electronic display 12 may include driver circuitry (e.g., display driver circuitry) and/or a display panel. The electronic device 10 may also have the one or more antennas 32 electrically coupled to the processor core complex 18. The electronic device 10 may be any suitable electronic device. To help illustrate, an example of the electronic device 10, a handheld device 10A, is shown in FIG. 2. The handheld device 10A may be a portable phone, a media player, a personal data organizer, a handheld game platform, or the like. For illustrative purposes, the handheld device 10A may be a smart phone, such as an IPHONE® model available from Apple Inc.

The handheld device 10A includes an enclosure 36 (e.g., housing). The enclosure 36 may protect interior components from physical damage or shield them from electromagnetic interference, such as by surrounding the electronic display 12. The electronic display 12 may display a graphical user interface (GUI) 38 having an array of icons. When an icon 34 is selected either by an input device 14 or a touch-sensing component of the electronic display 12, an application program may launch.

The input devices 14 may be accessed through openings in the enclosure 36. The input devices 14 may enable a user to interact with the handheld device 10A. For example, the input devices 14 may enable the user to activate or deactivate the handheld device 10A, navigate a user interface to a home screen, navigate a user interface to a user configurable application screen, activate a voice-recognition feature, provide volume control, or toggle between vibrate and ring modes.

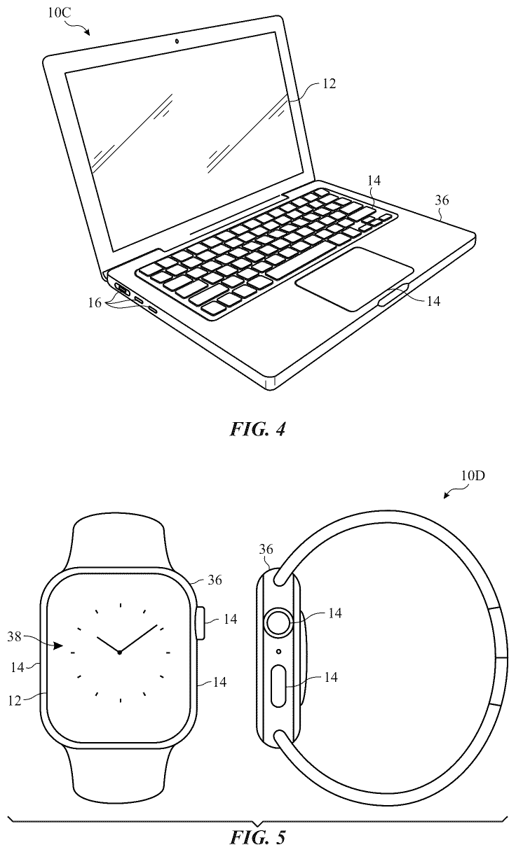

Another example of a suitable electronic device 10, specifically a tablet device 10B, is shown in FIG. 3. The tablet device 10B may be an IPAD® model available from Apple Inc. A further example of a suitable electronic device 10, specifically a computer 10C, is shown in FIG. 4. For illustrative purposes, the computer 10C may be a MACBOOK® or IMAC® model available from Apple Inc. Another example of a suitable electronic device 10, specifically a watch 10D, is shown in FIG. 5. For illustrative purposes, the watch 10D may be an APPLE WATCH® model available from Apple Inc. As depicted, the tablet device 10B, the computer 10C, and the watch 10D each also includes an electronic display 12, input devices 14, I/O ports 16, and an enclosure 36. The electronic display 12 may display a GUI 38.

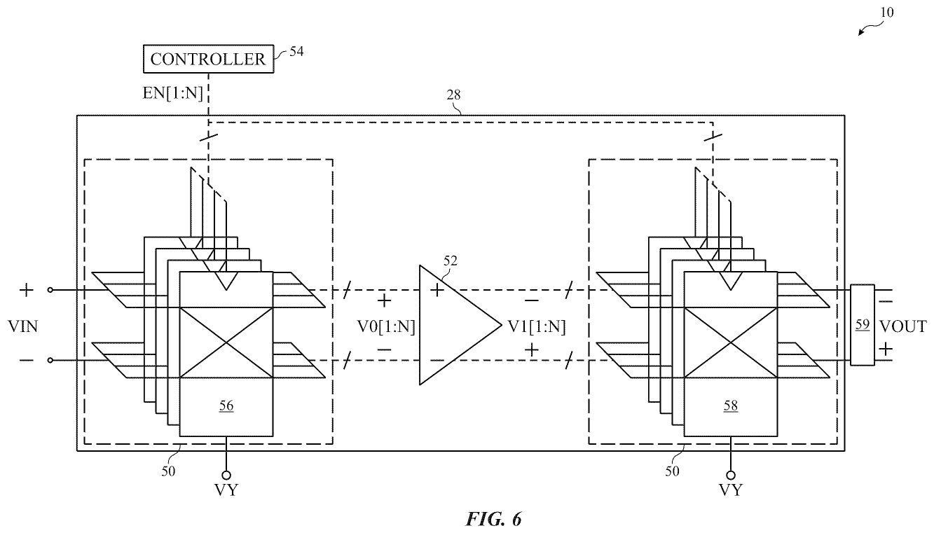

FIG. 6 is a block diagram of a portion of the electronic device 10 including the amplifier circuit 28 with a differential amplifier 52 and distributed chopper circuitry 50 having a shifting rest phase, according to embodiments of the present disclosure. The amplifier circuit 28 may include a differential amplifier 52 coupled to the distributed chopper circuitry 50 to generate output signals (e.g., the differential output signal, amplified signals, V_{OUT}). The electronic device 10 may include a controller 54 coupled to the distributed chopper circuitry 50 to control operations of the amplifier circuit 28 for generating the output signals. The controller 54 may include at least a portion of processing resources, processor cores, and/or logic circuitry of the processor core complex 18 discussed above.

The controller 54 may perform various operations including chopping activated portions of the amplifier circuit 28 for generating the output signals and shifting a rest phase through a remaining portion of the amplifier circuit 28 during each time step of an operation, among other possibilities. For example, the controller 54 may be referred to as a rest and chopping controller. The controller 54 may shift the rest phase during the operations of the amplifier circuit 28 such that at least a portion of the amplifier circuit 28 may be in a rest phase while a remainder of the amplifier circuit 28 may operate in an active phase.

The controller 54 may include one or more processors, one or more general purpose microprocessors, one or more ASICs, one or more FPGAs, or any combination thereof. The controller 54 may execute instructions stored in local memory 20 and/or the main memory storage device 22 of the electronic device 10 discussed above to perform operations, such as generating or transmitting control signals to the distributed chopper circuitry 50. The processor core complex 18 of the electronic device 10 discussed above, the amplifier circuit 28, or any other viable circuitry may include the controller 54. For example, an SoC may include the amplifier circuit 28 and the controller 54, among other possibilities. Additionally or alternatively, the controller 54 may implement the techniques of this disclosure using finite state machine circuitry.

The distributed chopper circuitry 50 may include multiple (e.g., N) input chopper circuits 56 (e.g., multiplexers) and multiple (e.g., N) output chopper circuits 58 (e.g., multiplexers). The differential amplifier 52 may be coupled to the input chopper circuits 56 and the output chopper circuits 58. Each input chopper circuit 56 and each output chopper circuit 58 may be coupled to a portion of the differential amplifier 52. The controller 54 may activate a portion of the amplifier circuit 28 to amplify input signals (e.g., the differential input signal) during operations of the amplifier circuit 28. Each operation may span over multiple time steps.

The controller 54 may generate control signals EN[1:N] during each time step of an operation of the amplifier circuit 28. The controller 54 may activate a number of (e.g., 1, 2, 3, 4, and so on) the input chopper circuits 56 and the output chopper circuits 58 while resting (e.g., deactivating) a remainder of (e.g., 1, 2, 3, 4, and so on) the input chopper circuits 56 and the output chopper circuits 58 during each time step. As such, each of the input chopper circuits 56 and the output chopper circuits 58 may have either of an active phase or a rest phase during each time step. Moreover, at least one input chopper circuits 56 and the output chopper circuits 58 may be in the rest phase during each time step.

For example, the controller 54 may activate a number of (e.g., N-M) input chopper circuits 56 and output chopper circuits 58 during a first time step of an operation of the amplifier circuit 28. The controller 54 may rest (e.g., deactivate) a remaining number of (e.g., M) input chopper circuits 56 and output chopper circuits 58 during the first time step. Each activated input chopper circuit 56 may generate an alternating voltage V₀ based on receiving an input voltage V_{IN} (e.g., the differential input signals). The activated input chopper circuits 56 may generate a set of alternating voltages V₀[1:N-M] based on receiving the input voltage V_{IN}. The resting input chopper circuits 56 may be open, removed, and/or be coupled to a neutral input terminal VY of the amplifier circuit 28. The neutral input terminal VY may include a ground terminal, a virtual ground terminal, among other possibilities. For example, the neutral input terminal VY may have a voltage value equal to zero or near zero volts, a virtual ground voltage value of the amplifier circuit 28, or a voltage value between that of the positive input terminal and the negative input terminal, among other possibilities. In some cases, the resting input chopper circuit 56 may not provide an output signal.

Moreover, the differential amplifier 52 may generate a set of amplified alternating voltages V₁[1:N-M] based on receiving the set of alternating voltages V₀[1:N-M]. The activated output chopper circuits 58 may generate an output signal V_{OUT} based on receiving the set of amplified alternating voltages V₁[1:N-M]. In some embodiments, the electronic device 10 and/or the amplifier circuit 28 may include an integrator 59 such as an attenuator, a low-pass filter, or a buffer amplifier to attenuate high-frequency components of the output signal V_{OUT}. The integrator 59 may output the output signal V_{OUT}, by combining and/or filtering the output signals V_{OUT} of the activated output chopper circuits 58.

With the foregoing in mind, each input chopper circuit 56 may be paired with an output chopper circuit 58 based on the respective transistors L and R being paired. Each pair of input chopper circuit 56 and output chopper circuit 58 may be activated or deactivated together based on a respective portion of the control signals EN[1:N]. For example, a first input chopper circuit 56-1 paired with a first output chopper circuit 58-1 may receive a respective portion of the control signals EN[1]. Moreover, each pair of input chopper circuit 56 and output chopper circuit 58 may be coupled to and control a respective portion of the differential amplifier 52 coupled thereto.

During each time step, the controller 54 may activate a number of (e.g., N-M) the pairs of input chopper circuits 56 and output chopper circuits 58 while resting a remainder of (e.g., M) pairs of the input chopper circuits 56 and output chopper circuits 58. That is, each of the pairs of input chopper circuits 56 and output chopper circuits 58 may have either of an active phase or a rest phase during each time step. At least one pair of input chopper circuit 56 and output chopper circuit 58 may be in the rest phase during each time step.

Each activated pairs of input chopper circuits 56 and output chopper circuits 58 may activate the respective portion of the differential amplifier 52 to generate a respective amplified alternating voltage V₁ during each time step. The rested pairs of input chopper circuits 56 and output chopper circuits 58 may rest the respective portions of the differential amplifier 52 during each time step. The rested pairs of input chopper circuits 56 and output chopper circuits 58 and the respective portions of the differential amplifier 52 may be open or removed.

During an operation of the amplifier circuit 28, the controller 54 may shift the rest phase to one or more subsequent pairs of input chopper circuits 56 and output chopper circuits 58 at each time step. That is, at each time step, the controller 54 may activate at least one of the deactivated pairs of input chopper circuits 56 and output chopper circuits 58 and deactivate at least one of the activated pairs of input chopper circuits 56 and output chopper circuits 58. The controller 54 may cyclically rotate the rest phase through the pairs of input chopper circuits 56 and output chopper circuits 58 by shifting the rest phase through the pairs of input chopper circuits 56 and output chopper circuits 58. For example, the controller 54 may cyclically shift the rest phase back to a first pair of input chopper circuit 56 and output chopper circuit 58 after shifting the rest phase through the entirety of the pairs of input chopper circuits 56 and output chopper circuits 58 during the operation. As such, each of the pairs of input chopper circuits 56 and output chopper circuits 58 may be rested equally (e.g., at least once) when the controller 54 shifts the rest phase through the entirety of the pairs of input chopper circuits 56 and output chopper circuits 58 during the operation of the amplifier.

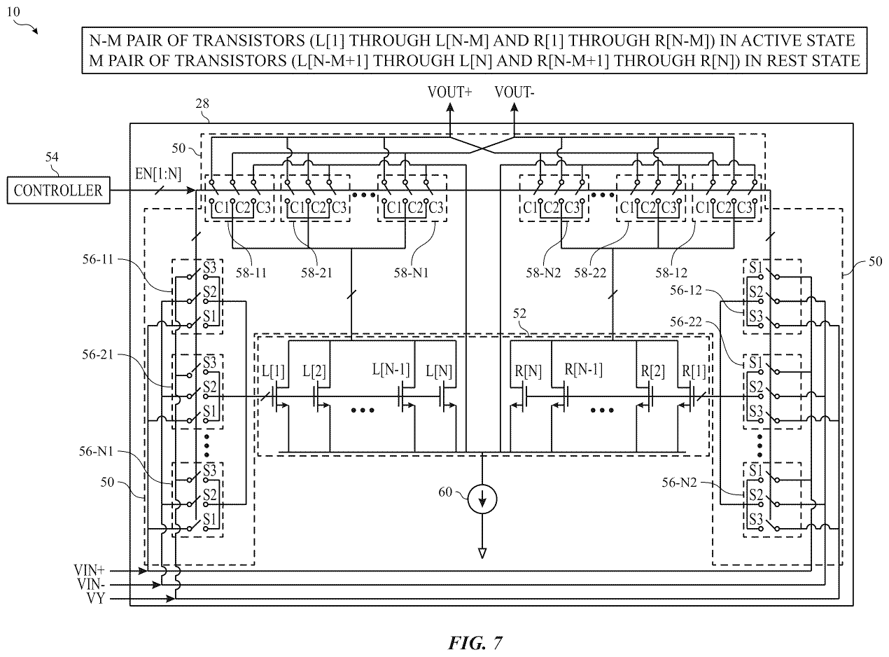

FIG. 7 is a circuit diagram of a portion of the electronic device 10 including the amplifier circuit 28 with the differential amplifier 52 and the distributed chopper circuitry 50 having a shifting rest phase, according to embodiments of the present disclosure. The amplifier circuit 28 may include multiple transistors L and R, a set of input chopper circuits 56 (e.g., modulators), and a set of output chopper circuits 58 (e.g., demodulators). Each output chopper circuit 58 may be associated with an input chopper circuit 56. Each input chopper circuit 56 and a respective output chopper circuit 58 may be controlled by one or more control signals EN, as will be appreciated.

Each input chopper circuit 56 and each output chopper circuit 58 may be coupled to a set of switches S1, S2, S3, C1, C2, and C3 to select different input and output signals. For example, each input chopper circuit 56 may selectively connect each transistor L or R of a transistor pair L and R to a first input terminal, a second input terminal, or a third input terminal of the amplifier based 28 on a value of the one or more control signals EN. Each output chopper circuit 58 may selectively connect each transistor L or R of the transistor pair L and R to a first output terminal, a second output terminal, or a third output terminal of the amplifier circuit 28 based on the value of the one or more control signals EN.

In the depicted embodiment, the distributed chopper circuitry 50 may include multiple (e.g., N) input chopper circuits 56-[1:N] and multiple (e.g., N) output chopper circuits 58-[1:N]. Each input chopper circuit 56-[1:N] may be split to a first half 56-[1:N]1 and a second half 56-[1:N]2. For example, a first input chopper circuit 56-1 may include a first half 56-11 and a second half 56-12, a second input chopper circuit 56-2 may include a first half 56-21 and a second half 56-22, and a last input chopper circuit 56-N may include a first half 56-N1 and a second half 56-N2.

Each half of each input chopper circuit 56-[1:N] may include a first switch S1, a second switch S2, and a third switch S3. The first switches S1 of each half of the input chopper circuits 56-[1:N] may be connected to each other. The second switches S2 of each half of the input chopper circuits 56-[1:N] may be connected to each other. The third switches S3 of each half of the input chopper circuits 56-[1:N] may be connected to each other. The switches S1, S2, and S3 of each half of the input chopper circuits 56-[1:N] may each receive a respective portion of the control signals EN[1:N]. The controller 54 may open and close the switches S1, S2, and S3 of each half of the input chopper circuits 56-[1:N] by generating the control signals EN[1:N].

The input terminals of the first switches S1 of each half of the input chopper circuits 56-[1:N] may be coupled to a positive input terminal V_{IN+} of the amplifier circuit 28. The input terminals of the second switches S2 of each half of the input chopper circuits 56-[1:N] may be coupled to a negative input terminal V_{IN-} of the amplifier circuit 28. The positive input terminal V_{IN+} and the negative input terminal V_{IN-} may form the e.g., the differential input signals. Moreover, the input terminals of the third switches S3 of each half of the input chopper circuits 56-[1:N] may be coupled to the neutral input terminal VY of the amplifier circuit 28. As mentioned above, the neutral input terminal VY may have any viable voltage value such as a voltage value equal to zero or near zero volts, a virtual ground voltage value of the amplifier circuit 28, or a voltage value between that of the positive input terminal and the negative input terminal, among other possibilities.

As mentioned above, the distributed chopper circuitry 50 may include multiple (e.g., N) output chopper circuits 58-[1:N]. Each output chopper circuit 58-[1:N] may be split to a first half 58-[1:N]1 and a second half 58-[1:N]2. For example, a first output chopper circuit 58-1 may include a first half 58-11 and a second half 58-12, a second output chopper circuit 58-2 may include a first half 58-21 and a second half 58-22, and a last output chopper circuit 58-N may include a first half 58-N1 and a second half 58-N2.

Each half of each output chopper circuit 58-[1:N] may include a first switch C1, a second switch C2, and a third switch C3. The first switches C1 of each half of the output chopper circuits 58-[1:N] may be connected to each other, the second switches C2 of each half of the output chopper circuits 58-[1:N] may be connected to each other, and the third switches C3 of each half of the output chopper circuits 58-[1:N] may be connected to each other. The switches C1, C2, and C3 of each half of the output chopper circuits 58-[1:N] may each receive a respective portion of the control signals EN[1:N]. As such, the controller 54 may open and close the switches C1, C2, and C3 of each half of the output chopper circuits 58-[1:N] by generating the control signals EN[1:N]. Output terminals of the first switches C1 of each half of the output chopper circuits 58-[1:N] may be coupled to a positive output terminal V_{OUT+} of the amplifier circuit 28. Moreover, output terminals of the second switches C2 of each half of the output chopper circuits 58-[1:N] may be coupled to a negative output terminal V_{OUT-} of the amplifier circuit 28.

The differential amplifier 52 may include (e.g., N) left side transistors L[1:N], multiple (e.g., N) right side transistors R[1:N], and a current source 60. Each left side transistor L[1:N] may have a gate terminal coupled to a respective half of the input chopper circuits 56-[1:N]1, and a drain terminal that is coupled to a respective half of the output chopper circuits 58-[1:N]1. Moreover, each right side transistor R[1:N] may have a gate terminal coupled to a respective half of the input chopper circuits 56-[1:N]2, and a drain terminal that is coupled to a respective half of the output chopper circuits 58-[1:N]2. The differential amplifier 52 may include a data bus including multiple data lines coupling (e.g., separately coupling) each of the transistors L[1:N] and R[1:N] to the respective halves of the input chopper circuits 56-[1:N]1 and the respective halves of the output chopper circuits 58-[1:N]1. In the depicted embodiment, output terminals of the switches S1, S2, and S3 of each half of the input chopper circuits 56-[1:N]1 may be coupled to a gate terminal of a respective left side transistor L[1:N]. Output terminals of the switches S1, S2, and S3 of each half of the input chopper circuits 56-[1:N]2 may be coupled to a gate terminal of a respective right side transistor R[1:N].

Moreover, input terminals of the switches C1, C2, and C3 of each half of the output chopper circuits 58-[1:N]1 may be coupled to the drain terminals of the left side transistor L[1:N]. Each of the third switches C3 may couple the drain terminal of the respective left side transistor L[1:N] coupled thereto to a source terminal of the respective left side transistor L[1:N] when shorted. Input terminals of the switches C1, C2, and C3 of each half of the output chopper circuits 58-[1:N]2 may be coupled to the drain terminals of the right side transistor R[1:N]. Each of the third switches C3 may couple the drain terminal of the respective right side transistor R[1:N] coupled thereto to a source terminal of the respective right side transistor R[1:N] when shorted.

Each transistor L[1:N] and R[1:N] may provide a portion of a positive or a negative signal of the differential output signal V_{OUT} during an operation of the amplifier circuit 28. The output signals of each of the transistor L[1:N] and R[1:N] may cumulatively combine at an input terminal of the output chopper circuits 58-[1:N]1 and 58-[1:N]2, respectively. As such, the halves of the output chopper circuits 58-[1:N]1 may receive the positive or the negative signal of the differential output signal V_{OUT}. Moreover, at each time during the operation of the amplifier circuit 28, the halves of the output chopper circuits 58-[1:N]2 may receive an inverted signal of the differential output signal V_{OUT}. The activated halves of the output chopper circuits 58-[1:N] may output the respective received portions of the differential output signal V_{OUT}.

Each input chopper circuit 56-[1:N] may be paired with an output chopper circuit 58-[1:N] based on the respective transistors L[1:N] and R[1:N] being paired. Moreover, each pair of input chopper circuits 56-[1:N] and output chopper circuits 58-[1:N] may activate and deactivate a pair of transistors L and R coupled thereto. In particular, each pair of input chopper circuits 56-[1:N] and output chopper circuits 58-[1:N] may activate and deactivate a respective pair of transistors L[1:N] and R[1:N] based on a respective portion of the control signals EN[1:N]. As such, each pair of input chopper circuits 56-[1:N] and output chopper circuits 58-[1:N] and the respective pair of transistors L[1:N] and R[1:N] may be activated or deactivated together based on a respective portion of the control signals EN[1:N].

Each operation of the amplifier circuit 28 may span over multiple time steps. Moreover, the controller 54 may activate a number of (e.g., N-M) the pairs of input chopper circuits 56-[1:N] and output chopper circuits 58-[1:N] while resting a remainder of (e.g., M) pairs of the input chopper circuits 56-[1:N] and output chopper circuits 58-[1:N] during each time step. That is, each of the pairs of input chopper circuits 56-[1:N] and output chopper circuits 58-[1:N] with the respective pairs of transistors L[1:N] and R[1:N] may have either of an active phase or a rest phase during each time step.

The controller 54 may activate a number of (e.g., N-M) pairs of the input chopper circuits 56-[1:N] and the output chopper circuits 58-[1:N] with the respective pairs of the transistors L[1:N] and R[1:N] during each time step. The controller 54 may chop the activated pairs of the input chopper circuits 56-[1:N] and the output chopper circuits 58-[1:N] by chopping or alternatively toggling the switches S1 and S2 and/or C1 and C2 to activate a pair of transistors L and R using a chopping frequency during an active phase of the paired transistors L and R. A voltage across a source and drain of each activated transistor L and R may become equal, nearly equal, or relatively equal upon activation. Each activated transistor L and R may drive the positive or the negative signal of the differential output signal V_{OUT}.

In specific cases, the controller 54 may activate only one of the paired transistors L and R at each time during an active phase of the paired transistors L and R. It should be appreciated that in some cases, activating and deactivating the paired transistors L and R using a chopping frequency may cause overlapping activated and/or deactivated periods of the paired transistors L and R. The chopping frequency may be associated with a duration of one or more time steps of an operation of the amplifier circuit 28.

In particular, the controller 54 may toggle the switches S1 and S2 of each of the activated input chopper circuits 56-[1:N] based on the chopping frequency. The activated input chopper circuits 56-[1:N] may toggle between providing a positive input voltage of the positive input terminal V_{IN+} to the gate terminals of the activated transistors L[1:N] and R[1:N]. As such, the controller 54 may toggle each transistor L or R of each pair of activated transistors L and R between an activated state and a deactivated state. For example, at each time, one of the paired transistors L or R may become deactivated during an active phase of the paired transistors L and R based on the chopping frequency. The activated transistors L or R (e.g., the chopped transistors L and R) may generate a positive output voltage of the amplifier circuit 28. The controller 54 may couple the deactivated transistors L or R to the negative input terminal V_{IN-} to receive a negative input voltage.

The controller 54 may toggle the switches C1 and C2 of each of the activated output chopper circuits 58 based on the chopping frequency, for example, while opening the third switch C3 of each of the deactivated output chopper circuits 58. As such, the activated output chopper circuits 58 may provide the positive output voltage to the positive output terminal V_{OUT+} of the amplifier circuit 28. It should be appreciated that in some embodiments, the amplifier circuit 28 may include impedance adjustment circuitry (not shown for simplicity) to adjust a gain of the positive output voltage. For example, the impedance adjustment circuitry may be coupled to output terminals V_{OUT+} and V_{OUT-} to increase the gain of amplifier circuit 28.

Moreover, the controller 54 may rest a remainder of (e.g., M) the pairs of the input chopper circuits 56-[1:N] and the output chopper circuits 58-[1:N] with the respective pairs of the transistors L[1:N] and R[1:N] during each time step. The controller 54 may deactivate both of the paired transistors L and R during a rest phase of the paired transistors L and R. For example, the controller 54 may open the switches S1 and S2 and close the third switches S3 of each of the rested input chopper circuits 56-[1:N] and/or open the switches C1 and C2 and close the third switches C3 of each of the rested output chopper circuits 58-[1:N]. In some embodiments, the amplifier circuit 28 may include a number of (e.g., M) spare pairs of the input chopper circuits 56-[1:N] and output chopper circuits 58-[1:N] and spare pairs of transistors L[M:N] and R[M:N]. In some cases, the controller 54 may rest a number of resting phases at each time step based on the number of spare pairs of the input chopper circuits 56-[1:N] and output chopper circuits 58-[1:N] and spare pairs of transistors L[M:N] and R[M:N].

As mentioned above, the controller 54 may shift the rest phase to one or more subsequent pairs of input chopper circuits 56-[1:N] and output chopper circuits 58-[1:N] and pairs of transistors L[1:N] and R[1:N] at each time step. As such, the controller 54 may generate different control signals EN[1:N] for different time steps during an operation of the amplifier circuit 28. It should be appreciated that in different cases, the controller 54 may activate and/or deactivate different pairs and/or a different number of the pairs of input chopper circuits 56-[1:N] and output chopper circuits 58-[1:N].

At an time step, the rested transistors L[1:N] and R[1:N] may release at least a portion of undesired trapped electrical charges while deactivated. For example, a rested transistor L[1:N] or R[1:N] may release at least a portion of the undesired electrical charges trapped in a semiconductor material (e.g., Complementary Metal-Oxide-Semiconductor (CMOS)) of the transistor L[1:N] or R[1:N] during previous active phases of the transistor L[1:N] or R[1:N]. As such, the rested transistor L[1:N] or R[1:N] may exhibit reduced random telegraph noise (RTN) and/or flicker noise to generate at least a portion of the output signals V_{OUT} (e.g., amplified signals) with an improved signal-to-noise ratio (SNR) during subsequent active phases of the transistor L[1:N] or R[1:N]. Moreover, as mentioned above, the rest phase may cyclically rotate through the pairs of input chopper circuits 56-[1:N] and output chopper circuits 58-[1:N] and the respective transistors L[1:N] and R[1:N]. Accordingly, the amplifier circuit 28 may generate the output signals V_{OUT} with an improved SNR.

By way of example, the controller 54 may generate a first set of control signals EN[1:N] during a first time step, a second set of control signals EN[1:N] during a second time step subsequent to the first time step, and so on. In some embodiments, the amplifier circuit 28 may include one spare pair of input chopper circuit 56 and output chopper circuit 58 and one spare pair of transistors L and R. In such embodiments, the first set of control signals EN[1:N] may be associated with activating the transistors L[1:N−1] and R[1:N−1] while resting the transistors L[N] and R[N]. The controller 54 may cyclically shift the rest phase back to a first pair of input chopper circuit 56-1 and output chopper circuit 58-1 and a first pair of transistors L[1] and R[1] subsequent to resting a last pair of the input chopper circuits 56[N] and the output chopper circuits 58[N] and the last pair of the transistors L[N] and R[N]. As such, the second set of control signals EN[1:N] may be associated with activating the transistors L[2:N] and R[2:N] while resting the transistors L[1] and R[1].

In alternative or additional embodiments, the amplifier circuit 28 may include two spare pairs of input chopper circuits 56 and output chopper circuits 58 and two spare pairs of transistors L and R. At each time step, the controller 54 may shift the rest phase by a resting frequency corresponding to a number of pairs of input chopper circuits 56[N] and output chopper circuits 58[N] and the associated transistors L[N] and R[N]. In some cases, the controller 54 may shift the rest phase by one pair of input chopper circuit 56 and output chopper circuit 58 and one pair of transistors L and R at each time step. As such, the first set of control signals EN[1:N] may be associated with activating the transistors L[1:N−2] and R[1:N−2] while resting the transistors L[N−1: N] and R[N−1: N]. Moreover, the second set of control signals EN[1:N] may be associated with activating the transistors L[3:N] and R[3:N] while resting the transistors L[N:1] and R[N:1]. In alternative or additional cases, the controller 54 may shift the rest phase by two pairs of input chopper circuits 56 and output chopper circuits 58 and two pairs of transistors XX at each time step. In such cases, the first set of control signals EN[1:N] may be associated with activating the transistors L[1:N−2] and R[1:N−2] while resting the transistors L[N−1: N] and R[N−1: N]. Moreover, the second set of control signals EN[1:N] may be associated with activating the transistors L[3:N] and R[3:N] while resting the transistors L[1:2] and R[1:2].

Accordingly, at each time step, the controller 54 may activate at least one of the deactivated pairs of input chopper circuits 56-[1:N] and output chopper circuits 58-[1:N] and pairs of transistors L and R, and deactivate at least one of the activated pairs of input chopper circuits 56-[1:N] and output chopper circuits 58-[1:N] and pairs of transistors L[1:N] and R[1:N]. Furthermore, each of the pairs of input chopper circuits 56-[1:N] and output chopper circuits 58-[1:N] and pairs of transistors L[1:N] and R[1:N] may be rested equally (e.g., at least once) when the controller 54 cyclically rotates the rest phase through the entirety of the pairs of input chopper circuits 56-[1:N] and output chopper circuits 58-[1:N] and pairs of transistors L[1:N] and R[1:N] during the operation of the amplifier.

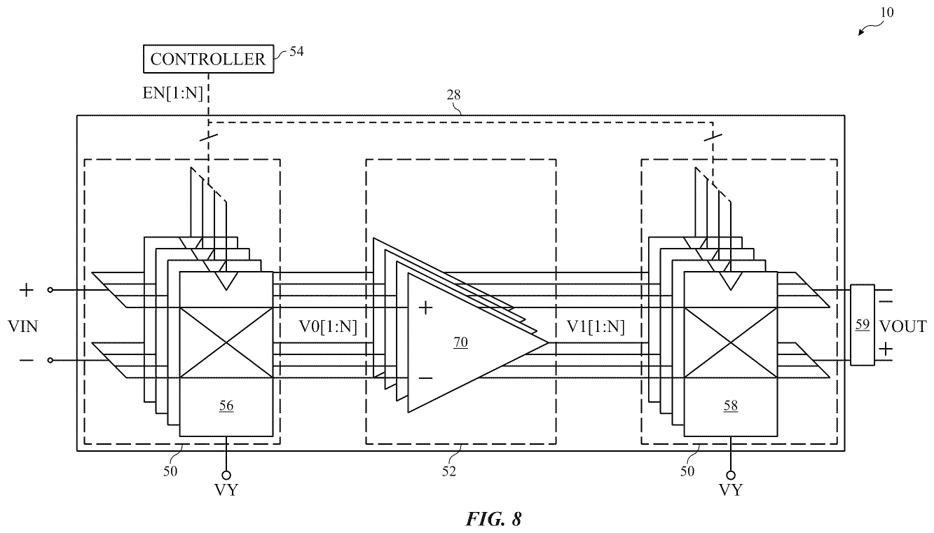

FIG. 8 is a block diagram of a portion of the electronic device 10 including the amplifier circuit 28 having the distributed chopper circuitry 50 and the differential amplifier 52 including multiple (e.g., N) segments 70, according to embodiments of the present disclosure. As discussed above, the distributed chopper circuitry 50 may include multiple (e.g., N) input chopper circuits 56 and multiple (e.g., N) output chopper circuits 58. Moreover, each input chopper circuit 56 may be paired with an output chopper circuit 58 based on the respective transistors L and R being paired. Furthermore, each input chopper circuit 56 and each output chopper circuit 58 may be coupled to a portion of the differential amplifier 52. In the depicted embodiment, each pair of the input chopper circuits 56 and the output chopper circuits 58 may be coupled to a respective segment 70 of the differential amplifier 52.

The controller 54 may generate the control signals EN[1:N] to activate and deactivate each pair of input chopper circuits 56 and output chopper circuits 58 and the respective segments 70 coupled thereto. Each activated pair of the input chopper circuits 56 and the output chopper circuits 58 and the respective segments 70 may generate a portion of the output signal V_{OUT}. For example, the output signals V_{OUT} of each of the activated pairs of the input chopper circuits 56 and the output chopper circuits 58 and the respective segments 70 may cumulatively combine at the integrator 59 (or an output terminal of the amplifier circuit 28) to generate the output signal V_{OUT}.

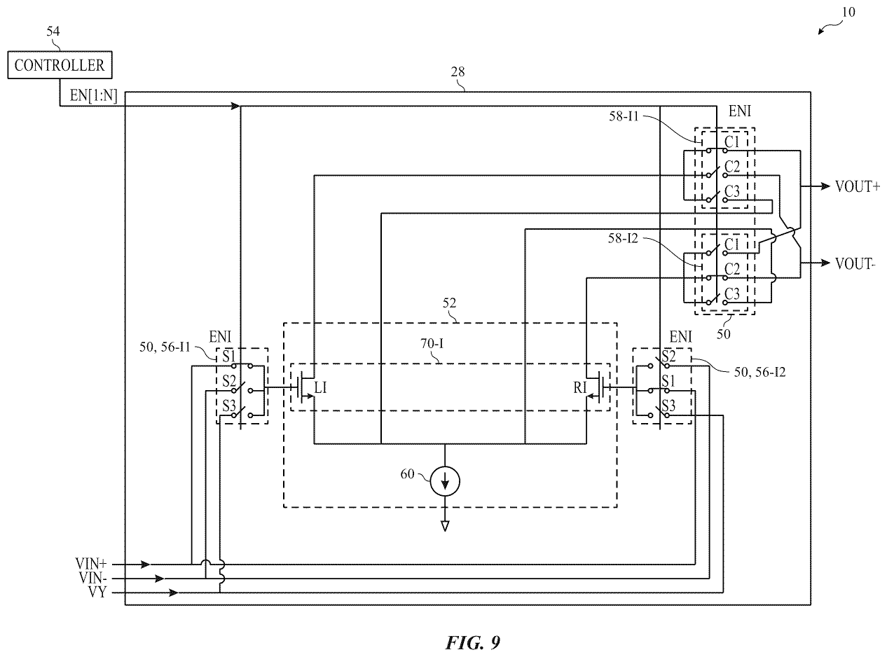

FIG. 9 is a circuit diagram of a portion of the electronic device 10 depicting a segment 70-I of multiple segments 70-[1:N] of the amplifier circuit 28, according to embodiments of the present disclosure. In the depicted embodiment, a single pair of input chopper circuit 56-I and output chopper circuit 58-I and the respective segment 70-I of the differential amplifier 52 is shown. However, it should be appreciated that the pair of the input chopper circuit 56-I and the output chopper circuit 58-I and the respective segment 70-I is associated with only a portion of the amplifier circuit 28 and is provided by the way of example.

In some embodiments, a remainder of the pairs of input chopper circuits 56-[1:N−1] and output chopper circuits 58-[1:N−1] and the respective segments 70-[1:N−1] of the differential amplifier 52 may have similar circuitry compared to the depicted pair of the input chopper circuit 56-I and the output chopper circuit 58-I and the respective segment 70-I. For example, the remainder of the pairs of input chopper circuits 56-[1:N−1] and output chopper circuits 58-[1:N−1] and the respective segments 70-[1:N−1] may be coupled in parallel to the depicted pair of the input chopper circuit 56-I and the output chopper circuit 58-I and the respective segment 70-I. Moreover, the output signals of each of the activated pairs of the input chopper circuits 56 and the output chopper circuits 58 and the respective segments 70 may cumulatively combine at output terminals V_{OUT+} and V_{OUT-} of the amplifier circuit 28 to generate the output signal V_{OUT}.

The depicted portion of the differential amplifier 52 may include a segment 70-I and a current source 60. The segment 70-I of the differential amplifier 52 may include a left side transistor LI and a right side transistor RI. The left side transistor LI may have a gate terminal coupled to a half of the input chopper circuits 56-I1, and a drain terminal that is coupled to a half of the output chopper circuit 58-I1. Moreover, the right side transistor RI may have a gate terminal coupled to a half of the input chopper circuits 56-I2, and a drain terminal that is coupled to a half of the output chopper circuit 58-I2. In the depicted embodiment, the output terminals of the switches S1, S2, and S3 of the half of the input chopper circuits 56-I1 may be coupled to (e.g., only coupled to, directly coupled to) the gate terminal of the left-side transistor LI. The output terminal of the switches S1, S2, and S3 of the half of the input chopper circuits 56-I2 may be coupled to (e.g., only coupled to, directly coupled to) a gate terminal of the right-side transistor RI.

Moreover, the input terminals of the switches C1, C2, and C3 of the half of the output chopper circuit 58-I1 may be coupled to the drain terminal of the left side transistor LI. The input terminal of the switches C1, C2, and C3 of the half of the output chopper circuit 58-I2 may be coupled to the drain terminal of the right side transistor RI. A voltage across a source and drain of each activated transistor L[I] and R[I] may become equal, nearly equal, or relatively equal upon activation. Each of the transistors LI and RI of the segment 70[I] may provide a portion of a positive or a negative signal of the differential output signal V_{OUT} when activated during an operation of the amplifier circuit 28. The output signals of each of the activated transistor L[1:N] and R[1:N] of the segments 70[1:N] may cumulatively combine at an output terminal of the output chopper circuits 58-[1:N]1 and 58-[1:N]2, respectively. The segments 70-[1−N−1] are not shown for simplicity. As such, the output signals of each of the activated pairs of the input chopper circuits 56 and the output chopper circuits 58 and the respective segments 70 may cumulatively combine (e.g., in current domain) at output terminals V_{OUT+} and V_{OUT-} of the amplifier circuit 28 to generate the output signal V_{OUT}.

The controller 54 may generate the control signals EN[1:N] to activate and deactivate each pair of input chopper circuits 56-[1:N] and output chopper circuits 58-[1:N] and the respective segments 70-[1:N] coupled thereto. Moreover, the controller 54 may deactivate both of the paired transistors LI and RI during a respective rest phase. For example, the controller 54 may open the switches S1 and S2 and close the third switch S3 of the rested input chopper circuit 56-I and/or open the switches C1 and C2 and close the third switch C3 of the rested output chopper circuit 58-I to rest the paired transistors L[I] and R[I]. As mentioned above, the controller 54 may shift the rest phase to one or more subsequent pairs of input chopper circuits 56-[1:N] and output chopper circuits 58-[1:N] and pairs of transistors L[1:N] and R[1:N] at each time step. As such, the controller 54 may generate different control signals EN[1:N] for different time steps during an operation of the amplifier circuit 28. It should be appreciated that in different cases, the controller 54 may activate and/or deactivate different pairs and/or a different number of the pairs of input chopper circuits 56-[1:N] and output chopper circuits 58-[1:N].

The transistors LI and RI may release at least a portion of undesired trapped electrical charges while being rested. For example, the transistor LI or RI may release at least a portion of the undesired electrical charges trapped in a semiconductor material (e.g., CMOS) of the transistor LI or RI during previous active phases of the transistor LI or RI while being rested. As such, the rested transistor LI or RI] may exhibit reduced RTN and/or flicker noise to generate at least a portion of the output signals V_{OUT} (e.g., amplified signals) with an improved SNR during subsequent active phases of the transistor LI or RI. Moreover, as mentioned above, the rest phase may cyclically rotate through the pairs of input chopper circuits 56-[1:N] and output chopper circuits 58-[1:N] and the respective transistors L[1:N] and R[1:N]. Furthermore, it should be appreciated that the differential amplifier 52 may include a data bus including multiple data lines coupling (e.g., separately coupling) each of the transistors L[1:N] and R[1:N] to the respective halves of the input chopper circuits 56-[1:N]1 and the respective halves of the output chopper circuits 58-[1:N]1. Accordingly, the amplifier circuit 28 may generate the output signals V_{OUT} with an improved SNR.

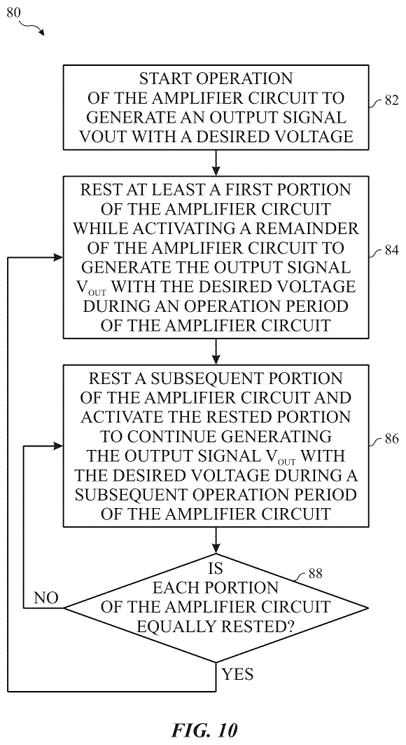

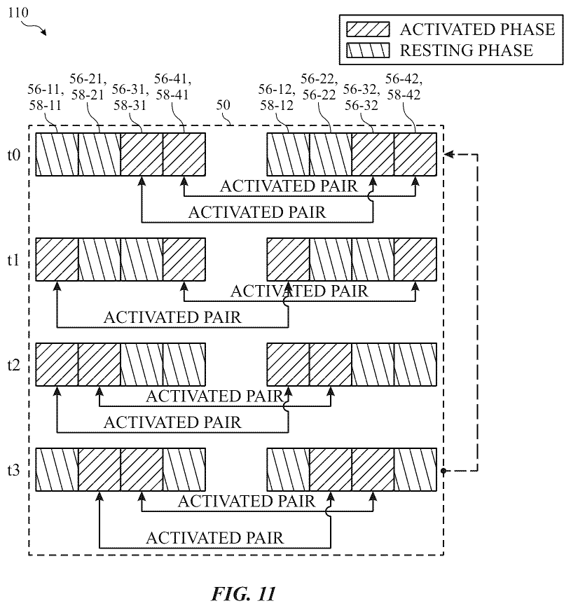

FIG. 10 is a process flow diagram illustrating an embodiment of a process 80 of providing an output signal V_{OUT} to one or more components of the electronic device 10, in accordance with an aspect of the present disclosure. For example, the controller 54 may generate the control signals EN[1:N] to cause the amplifier circuit 28 to output the output signal V_{OUT} to a power supply rail and/or a ground terminal coupled to the one or more components in the electronic device 10. The amplifier circuit 28 may include a differential amplifier such as the differential amplifiers 52 of FIGS. 6-9. As discussed above, the differential amplifiers 52 may include pairs of input chopper circuits 56 and output chopper circuits 58 each being coupled to respective transistors L and R. Moreover, one or more components of the electronic device 10 such as the electronic display 12, the input devices 14, the I/O ports 16, the processor core complex 18, the local memory 20, the main memory storage device 22, the network interface 24, the power supply 26, the transceiver 30, and the antennas 32, among other things, may include the amplifier circuit 28.

Although the following description of the process 80 is described with reference to the controller 54 of the electronic device 10, it should be noted that the process 80 may be performed by any other controller and/or processor disposed within the electronic device 10 or on other devices that may be capable of communicating with the electronic device 10. Additionally, although the following process 80 describes a number of operations that may be performed, it should be noted that the process 80 may be performed in a variety of suitable orders and all of the operations may not be performed. It should be appreciated that the process 80 may be executed by the amplifier circuit 28. In some embodiments, the process 80 may be stored as instructions included with the local memory 20 and/or the main memory storage device 22.

At block 82, the controller 54 may start operation of the amplifier circuit 28 to generate an output signal V_{OUT}. Alternatively or additionally, the controller 54 may receive an indication indicative of activating the amplifier circuit 28 to generate an output signal V_{OUT}. In different embodiments, the controller 54 may receive the indication from different components of the electronic device 10 or other components and/or devices that may be capable of communicating with the electronic device 10. For example, the output terminals of the amplifier circuit 28 may be coupled to a power supply rail and/or a ground terminal of one or more of the electronic display 12, the input devices 14, the I/O ports 16, the processor core complex 18, the local memory 20, the main memory storage device 22, the network interface 24, the power supply 26, the transceiver 30, and/or the antennas 32 of the electronic device 10.

At block 84, the controller 54 may generate a first set of control signals EN[1:N] to rest at least a first portion of the amplifier circuit 28 while activating a remainder of the amplifier circuit 28 to generate the output signal V_{OUT} during a first time step of the amplifier circuit 28. For example, the controller 54 may rest at least a first pair of input chopper circuits 56 and output chopper circuits 58 and the associated transistors L and R while activating a remainder of the amplifier circuit 28 to generate the output signal V_{OUT}. The controller 54 may chop or switch polarity of each transistor L or R of an activated pair of transistors L and R of the amplifier circuit 28 every one or more time steps based on a chopping frequency. For example, the controller 54 may chop or switch polarity of each pair of transistors L and R by chopping or switching between activating each activated pair of the input chopper circuits 56 and the output chopper circuits 58 based on the chopping frequency during an active phase of each pair of transistors L and R. Moreover, the controller 54 may deactivate or rest the remaining pairs of the input chopper circuits 56 and the output chopper circuits 58 and the respective transistors L and R. In different cases, the controller 54 may rest a different number of pairs of the input chopper circuits 56 and the output chopper circuits 58 and the respective transistors L and R.

At block 86, the controller 54 may generate a subsequent set of control signals EN[1:N] to rest a subsequent portion of the amplifier circuit 28 and activate the rested portion to continue generating the output signal V_{OUT} during a subsequent time step of the amplifier circuit 28. For example, the controller 54 may rest a subsequent pair of the input chopper circuits 56 and the output chopper circuits 58 and the respective transistors L and R in lieu of the first pair of the input chopper circuits 56 and the output chopper circuits 58 and the respective transistors L and R to continue generating the output signal V_{OUT}. For example, the controller 54 may shift the rest phase to the subsequent portion of the amplifier circuit 28.

The controller 54 may proceed to block 88 to determine whether each portion of the amplifier circuit 28 is rested equally. The controller 54 may track a rest phase of each portion of the amplifier circuit 28 by tracking a sequence of the portions, maintaining a counter value based on the number of the portions, among other possibilities. As such, the controller 54 may track deactivation of each portion of the amplifier circuit 28.

In response to determining that each portion of the amplifier circuit 28 is not equally rested, the controller 54 may return to block 84 to generate the first set of control signals EN[1:N]. As such, the controller 54 may rest at least the first portion of the amplifier circuit 28 while activating a remainder of the amplifier circuit 28 to generate the output signal V_{OUT} with the desired voltage during a subsequent time step of the amplifier circuit 28. Accordingly, the controller 54 may cyclically rotate the rest phase back to a first portion of the amplifier circuit 28 during the operation. Moreover, each of the portions of the amplifier circuit 28 may be rested equally (e.g., at least once) when the controller 54 shifts the rest phase through the entirety of the portions of the amplifier circuit 28 during the operation. It should be appreciated that the controller 54 may chop the activated portion of the amplifier circuit 28 during the operations of blocks 84 and 86 at a higher rate or speed based on the chopping frequency compared to the rate for shifting the rest phase to a subsequent portion of the amplifier circuit 28.

In response to determining that each portion of the amplifier circuit 28 is not equally rested, the controller 54 may return to block 86 to generate a subsequent set of control signals EN[1:N]. That is, the controller 54 may proceed by resting a subsequent portion of the amplifier circuit 28 and activating the rested portion to continue generating the output signal V_{OUT} during a subsequent time step of the amplifier circuit 28. At block 88, the controller 54 may keep returning to blocks 84 or 86 until an end of the operation of the amplifier circuit 28.

Accordingly, the controller 54 may rest at least one portion of the amplifier circuit 28 while activating a remainder of the amplifier circuit 28 to generate the output signal V_{OUT} during each time step of the amplifier circuit 28. Each portion (e.g., transistor pairs) of the amplifier circuit 28 may exhibit reduced RTN and/or flicker noise when generating the respective portion of the output signals V_{OUT} based on being rested. Accordingly, the amplifier circuit 28 may generate the output signals V_{OUT} with an improved SNR.

FIG. 11 is a timing diagram 110 of a first example of operations of distributed chopper circuitry 50 illustrating synchronized shifting of rest phases and active phases of four pairs of the input chopper circuits 56-[1:4] and the output chopper circuits 58-[1:4], according to embodiments of the present disclosure. It should be appreciated that the timing diagram 110, the distributed chopper circuitry 50, and the respective parameters are provided as non-limiting examples. For example, in alternative or additional embodiments, the distributed chopper circuitry 50 may include different number of pairs of the input chopper circuits 56-[1:N] and the output chopper circuits 58-[1:N], chopping frequency, and/or resting frequency.

Each input chopper circuit 56-[1:4] may be paired with an output chopper circuit 58-[1:4] based on the respective transistors L[1:4] and R[1:4] being paired. Moreover, each pair of input chopper circuits 56-[1:4] and output chopper circuits 58-[1:4] may activate and deactivate a pair of transistors L and R coupled thereto (not shown). In particular, each pair of input chopper circuits 56-[1:4] and output chopper circuits 58-[1:4] may activate and deactivate a respective pair of transistors L[1:4] and R[1:4] based on a respective portion of the control signals EN[1:N] discussed above. The controller 54 may chop the activated pairs of the input chopper circuits 56-[1:4] and the output chopper circuits 58-[1:4] and the respective transistors L[1:4] and R[1:4] between each time step t0 through t3. The controller 54 may chop the activated portion of the amplifier circuit 28 while shifting the resting phase. The activated pairs are illustrated with linking arrows at each time step. For example, in the depicted embodiment, the chopping frequency may be equal to a rate of shifting the resting phase. It should be appreciated that in alternative or additional embodiments, the chopping frequency may be independent of and/or have a higher rate compared to the rate of shifting the resting phase.

In timing diagram 110, each operation (e.g., rest cycle) of the amplifier circuit 28 may span over four time steps t0, t1, t2, and t3. During each time step, the controller 54 may chop two activated pairs of the input chopper circuits 56-[1:4] and the output chopper circuits 58-[1:4] while resting a remainder of (e.g., two) pairs of the input chopper circuits 56-[1:4] and the output chopper circuits 58-[1:4]. In the depicted embodiment, the controller 54 may shift the rest phase by a resting frequency of one time step.

That is, the controller 54 may generate control signals EN[1:4] to activate the input chopper circuits 56-11 and 56-21 and the output chopper circuits 58-12 and 58-22 at the first time step t0, activate the input chopper circuits 56-21 and 56-31 and the output chopper circuits 58-22 and 58-32 at the second time step t1, and so on. As such, the controller 54 may activate each of the paired input chopper circuits 56-[1:4] and the output chopper circuits 58-[1:4] and/or the respective transistors L and R with a shifting frequency of two based on a duration of an active phase of each pair corresponding to two time steps before being rested. Moreover, the controller 54 may cyclically rotate or shift the rest phase every four time steps t0, t1, t2, and t3 based on the resting frequency, chopping frequency, and the number of pairs (e.g., 4) of the input chopper circuits 56-[1:4] and the output chopper circuits 58-[1:4] and/or the respective transistors L and R.

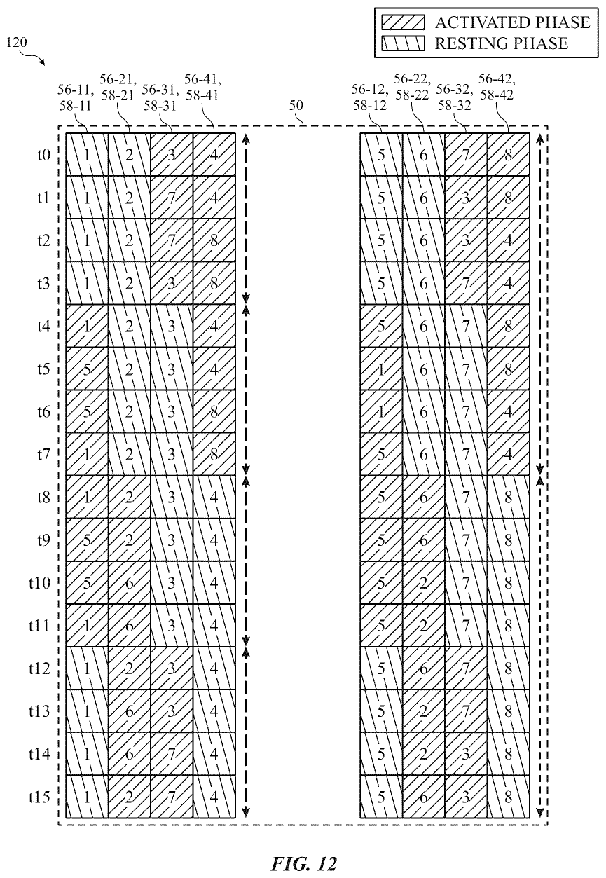

FIG. 12 is a timing diagram 120 illustrating a second example of operations of distributed chopper circuitry 50 for cyclically rotating a rest phase of four transistor pairs L[1:4] and R[1:4] of the amplifier circuit 28 every sixteen time steps while chopping each two transistor pairs L[1:4] and R[1:4] of the amplifier circuit 28 over four time steps, according to embodiments of the present disclosure. It should be appreciated that the timing diagram 120, the distributed chopper circuitry 50, and the respective parameters are provided as non-limiting examples. That is, in alternative or additional embodiments, the distributed chopper circuitry 50 may include different number of pairs of the input chopper circuits 56-[1:N] and the output chopper circuits 58-[1:N], chopping frequency, and/or resting frequency.

As discussed above, each input chopper circuit 56-[1:4] may be paired with an output chopper circuit 58-[1:4] based on the respective transistors L[1:4] and R[1:4] being paired. Moreover, each pair of input chopper circuits 56-[1:4] and output chopper circuits 58-[1:4] may activate and deactivate a pair of transistors L and R coupled thereto (not shown). In particular, each pair of input chopper circuits 56-[1:4] and output chopper circuits 58-[1:4] may activate and deactivate a respective pair of transistors L[1:4] and R[1:4] based on a respective portion of the control signals EN[1:N] discussed above. The controller 54 may chop the activated pairs of the input chopper circuits 56-[1:4] and the output chopper circuits 58-[1:4] and the respective transistors L[1:4] and R[1:4] between each time step t0 through t15. The controller 54 may chop the activated pairs while shifting the resting phase.

In timing diagram 120, each operation (e.g., rest cycle) of the amplifier circuit 28 may span over 16 time steps t0-t15 while chopping of each two transistor pairs L[1:4] and R[1:4] spans over four time steps (e.g., t0-t3, t4-t7, t8-t11, and t12-t15). As such, the chopping frequency may have a higher rate compared to the rate of shifting the resting phase. During each time step, the controller 54 may chop two activated pairs of the input chopper circuits 56-[1:4] and the output chopper circuits 58-[1:4] while resting a remainder of (e.g., two) pairs of the input chopper circuits 56-[1:4] and the output chopper circuits 58-[1:4]. In the depicted embodiment, the controller 54 may shift the rest phase by a resting frequency of four time steps.

That is, the controller 54 may generate control signals EN[1:4] to activate the input chopper circuits 56-11 and 56-21 and the output chopper circuits 58-12 and 58-22 at the time steps t0-t3, activate the input chopper circuits 56-21 and 56-31 and the output chopper circuits 58-22 and 58-32 at the time steps t4-t7, and so on. As such, the controller 54 may activate each of the paired input chopper circuits 56-[1:4] and the output chopper circuits 58-[1:4] and/or the respective transistors L and R with a shifting frequency of eight based on a duration of an active phase of each pair corresponding to eight time steps before being rested. Moreover, the controller 54 may cyclically rotate or shift the rest phase every sixteen time steps t0-t15 based on the resting frequency, shifting frequency, and the number of pairs (e.g., 4) of the input chopper circuits 56-[1:4] and the output chopper circuits 58-[1:4] and/or the respective transistors L and R.

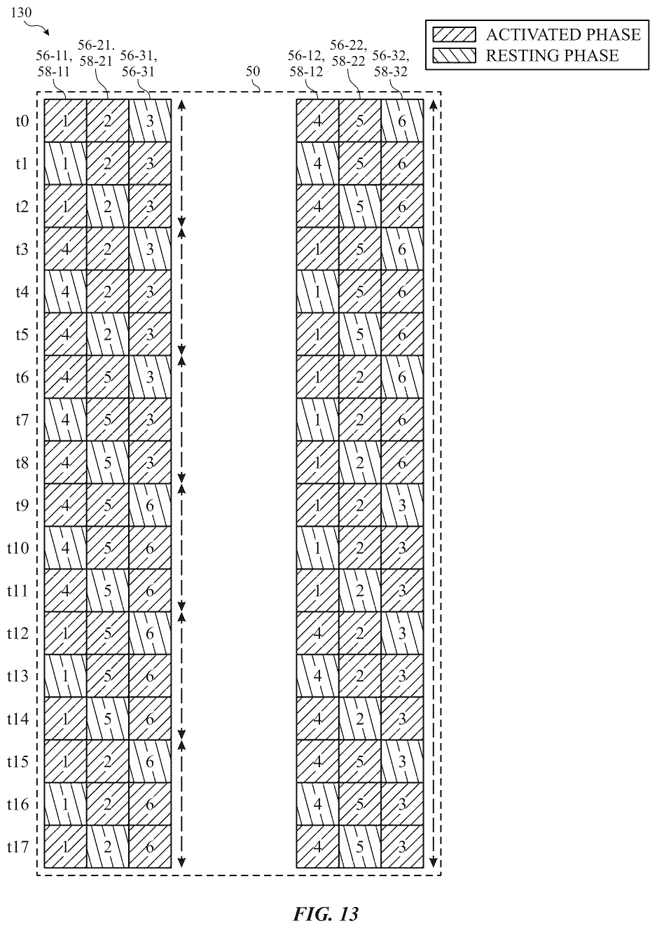

FIG. 13 is a timing diagram 130 illustrating a third example of operations of distributed chopper circuitry 50 for cyclically rotating a rest phase of four transistor pairs L[1:3] and R[1:3] of the amplifier circuit 28 every eighteen time steps while chopping each two transistor pairs L[1:3] and R[1:3] of the amplifier circuit 28 over three time steps, according to embodiments of the present disclosure. It should be appreciated that the timing diagram 130, the distributed chopper circuitry 50, and the respective parameters are provided as non-limiting examples. That is, in alternative or additional embodiments, the distributed chopper circuitry 50 may include different number of pairs of the input chopper circuits 56-[1:N] and the output chopper circuits 58-[1:N], chopping frequency, and/or resting frequency. [it takes 3 steps to finish resting of 3 transistors on each side—it takes 18 time steps to finish both chopping and resting—because the resting frequency here is higher than chopping frequency] [t0-t2 cycle]

As discussed above, each input chopper circuit 56-[1:3] may be paired with an output chopper circuit 58-[1:3] based on the respective transistors L[1:3] and R[1:3] being paired. Moreover, each pair of input chopper circuits 56-[1:3] and output chopper circuits 58-[1:3] may activate and deactivate a pair of transistors L and R coupled thereto (not shown). In particular, each pair of input chopper circuits 56-[1:3] and output chopper circuits 58-[1:3] may activate and deactivate a respective pair of transistors L[1:3] and R[1:3] based on a respective portion of the control signals EN[1:N] discussed above. The controller 54 may chop the activated pairs of the input chopper circuits 56-[1:3] and the output chopper circuits 58-[1:3] and the respective transistors L[1:3] and R[1:3] between each time step t0 through t17. The controller 54 may chop the activated pairs while shifting the resting phase.

In timing diagram 130, each operation (e.g., rest cycle) of the amplifier circuit 28 may span over 3 time steps t0-t2 while chopping of three transistor pairs L[1:3] and R[1:3] spans over eighteen time steps, chopping of each transistor pair taking 6 time steps. As such, the rate of shifting the resting phase may have a higher rate compared to the chopping frequency. During each time step, the controller 54 may chop two activated pairs of the input chopper circuits 56-[1:3] and the output chopper circuits 58-[1:3] while resting a remainder of (e.g., one) pairs of the input chopper circuits 56-[1:3] and the output chopper circuits 58-[1:3]. That is, during transition from each three time step (e.g., t0-t2, t3-t5, t6-t8, t9-t11, t12-t14, and t15-t17) to another (e.g. from t0-t2 to t3-t5, so on), the controller 54 may chop one of two activated pairs. In the depicted embodiment, the controller 54 may shift the rest phase by a resting frequency of one time step.

That is, the controller 54 may generate control signals EN[1:3] to activate the input chopper circuits 56-11 and 56-21 and the output chopper circuits 58-12 and 58-22 at the time steps t0-t2, activate the input chopper circuits 56-21 and 56-31 and the output chopper circuits 58-22 and 58-32 at the time steps t3-t5, and so on. As such, the controller 54 may activate each of the paired input chopper circuits 56-[1:3] and the output chopper circuits 58-[1:3] and/or the respective transistors L and R based on a duration of an active phase of each pair corresponding to two time steps before being rested. Moreover, the controller 54 may cyclically rotate or shift the rest phase every time steps based on the resting frequency, shifting frequency, and the number of pairs (e.g., 4) of the input chopper circuits 56-[1:3] and the output chopper circuits 58-[1:3] and/or the respective transistors L and R.

The specific embodiments described above have been shown by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ,” it is intended that such elements are to be interpreted under 35 U.S.C. 112(f). However, for any claims containing elements designated in any other manner, it is intended that such elements are not to be interpreted under 35 U.S.C. 112(f).

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

What is claimed is:

1. An amplifier circuit comprising:
a plurality of transistors configured to generate an output signal during an operation of the amplifier circuit spanning a plurality of time steps; and
a plurality of input chopper circuits coupled to the plurality of transistors, wherein:
a set of input chopper circuits of the plurality of input chopper circuits are configured to activate a set of transistors of the plurality of transistors during at least a first time step of the plurality of time steps; and
at least a first input chopper circuit of a remainder of the plurality of input chopper circuits is configured to deactivate at least a first transistor of the plurality of transistors during at least the first time step.

2. The amplifier circuit of claim 1, wherein at least a second input chopper circuit of the remainder of the plurality of input chopper circuits is configured to deactivate at least a second transistor of the plurality of transistors coupled thereto during at least the first time step.

3. The amplifier circuit of claim 1, wherein the first input chopper circuit is configured to activate the first transistor during a second time step of the plurality of time steps subsequent to the first time step.

4. The amplifier circuit of claim 3, wherein at least a third input chopper circuit of the plurality of input chopper circuits is configured to deactivate at least a third transistor of the plurality of transistors during the second time step.

5. The amplifier circuit of claim 4, wherein the first input chopper circuit is configured to cyclically deactivate the first transistor during a third time step of the plurality of time steps subsequent to the second time step based on each of the plurality of the input chopper circuits deactivating at least one transistor coupled thereto during at least one time step after the first time step.

6. The amplifier circuit of claim 1, wherein a fourth input chopper circuit of the plurality of input chopper circuits is configured to deactivate at least a fourth transistor of the plurality of transistors coupled thereto during at least the first time step, a second time step of the plurality of time steps, or both.

7. The amplifier circuit of claim 1, wherein each input chopper circuit of the plurality of input chopper circuits comprises a plurality of switches.

8. The amplifier circuit of claim 1, wherein the activated set of the transistors generate the output signal based on receiving a differential input signal and based on a chopping frequency associated with toggling paired transistors of the activated set of the transistors.

9. An electronic device comprising:
an amplifier circuit comprising:
a plurality of transistors configured to generate an output signal during an operation of the amplifier circuit spanning over a plurality of time steps; and
a plurality of input chopper circuit and output chopper circuit pairs, wherein each of the plurality of input chopper circuit and output chopper circuit pairs is coupled to at least two transistors of the plurality of transistors; and
a controller coupled to the amplifier circuit, wherein the controller is configured to generate control signals to deactivate at least two transistors of the plurality of transistors coupled to an input chopper circuit and output chopper circuit pair of the plurality of input chopper circuit and output chopper circuit pairs during a time step of the plurality of time steps.

10. The electronic device of claim 9, wherein the controller is configured to generate the control signals to activate the at least two transistors coupled to the input chopper circuit and output chopper circuit pair during a subsequent time step of the plurality of time steps.

11. The electronic device of claim 9, wherein each input chopper circuit of the plurality of input chopper circuit and output chopper circuit pairs comprises a respective plurality of switches.

12. The electronic device of claim 11, wherein the controller is configured to generate the control signals to open the respective plurality of switches of the input chopper circuit of the input chopper circuit and output chopper circuit pair during the time step to deactivate the at least two transistors coupled to the input chopper circuit and output chopper circuit pair.

13. The electronic device of claim 12, wherein the controller is configured to generate the control signals to close at least one of the respective plurality of switches of the input chopper circuit during a subsequent time step of the plurality of time steps to activate the at least two transistors coupled to the input chopper circuit and output chopper circuit pair.

14. The electronic device of claim 9, wherein activated transistors of the plurality of transistors differentially generate the output signal based on receiving a differential input signal during each of the plurality of time steps.

15. The electronic device of claim 9, wherein the controller is configured to cyclically generate the control signals to deactivate the at least two transistors coupled to the input chopper circuit and output chopper circuit pair during one or more subsequent time steps of the plurality of time steps subsequent to deactivating the at least two transistors of the plurality of transistors of each of the plurality of input chopper circuit and output chopper circuit pairs during at least one time step of the plurality of time steps subsequent to the time step.

16. Tangible, non-transitory, computer-readable media storing instructions that, when executed by processing circuitry, cause the processing circuitry to:
deactivate at least a first portion of an amplifier circuit while activating a remainder of the amplifier circuit to generate an output signal during a first time step;
deactivate a subsequent portion of the amplifier circuit and activate a first deactivated portion of the amplifier circuit to continue generating the output signal during a subsequent time step of the amplifier circuit based on a current time step not being a last time step to generate the output signal and each portion of the amplifier circuit not being deactivated during an equal number of time steps, wherein the first deactivated portion comprises the first portion of the amplifier circuit; and
deactivate the first portion of the amplifier circuit and activate a second deactivated portion of the amplifier circuit to continue generating the output signal during a subsequent time step of the amplifier circuit based on the current time step not being the last time step to generate the output signal and each portion of the amplifier circuit being deactivated during an equal number of time steps, wherein the second deactivated portion comprises the subsequent portion of the amplifier circuit.

17. The tangible, non-transitory, computer-readable media of claim 16, wherein the instructions cause the processing circuitry to track deactivation of each portion of the amplifier circuit to determine whether each portion of the amplifier circuit is deactivated during an equal number of time steps.

18. The tangible, non-transitory, computer-readable media of claim 16, wherein the instructions cause the processing circuitry to deactivate the amplifier circuit after the current time step based on determining that the current time step is the last time step to generate the output signal.

19. The tangible, non-transitory, computer-readable media of claim 16, wherein the instructions cause the processing circuitry to deactivate at least a first pair of transistors of a differential amplifier to deactivate the first portion of the amplifier circuit.

20. The tangible, non-transitory, computer-readable media of claim 16, wherein the instructions cause the processing circuitry to deactivate at least a first input chopper circuit of a differential amplifier to deactivate the first portion of the amplifier circuit.
